(19) United States
(12) Patent Application Publication
(10) Pub. No.: US 2023/0200230 A1
(43) Pub. Date: Jun. 22, 2023

(54) LIGHT-EMITTING DEVICE, LIGHT-EMITTING SUBSTRATE AND LIGHT-EMITTING APPARATUS

(71) Applicant: BOE TECHNOLOGY GROUP CO., LTD., Beijing (CN)

(72) Inventors: Yang LIU, Beijing (CN); Yuqian SUN, Beijing (CN)

(73) Assignee: BOE TECHNOLOGY GROUP CO., LTD., Beijing (CN)

(21) Appl. No.: 17/927,463

(22) PCT Filed: Nov. 22, 2021
(86) PCT No.: PCT/CN2021/132170

§ 371 Date: Nov. 23, 2022

(30) Foreign Application Priority Data
Feb. 25, 2021 (CN) 202110212633.9

(51) Int. Cl. H10K 85/60; H10K 59/35; C09K 11/06

(52) U.S. Cl. CPC H10K 85/6572; H10K 59/35; C09K 11/06; H10K 85/657; H10K 85/654; H10K 85/622; H10K 50/11

(57) ABSTRACT

A light-emitting device includes a first electrode and a second electrode that are arranged sequentially, and a light-emitting layer disposed between the first electrode and the second electrode; a material of the light-emitting layer includes a host material and a guest material; the host material includes a p-type material and an n-type material, the p-type material and the n-type material form an exciplex, and the p-type material and the n-type material satisfy a following condition: |HOMO_{p-type}−HOMO_{n-type}|≤0.2 eV; HOMO_{p-type} represents a highest occupied molecular orbital (HOMO) energy level of the p-type material, and HOMO_{n-type} represents a HOMO energy level of the n-type material.

### CROSS-REFERENCE TO RELATED APPLICATIONS

This application is a national phase entry under 35 USC 371 of International Patent Application No. PCT/CN2021/132170, filed on Nov. 22, 2021, which claims priority to Chinese Patent Application No. 202110212633.9, filed on Feb. 25, 2021, which are incorporated herein by reference in their entirety.

### TECHNICAL FIELD

The present disclosure relates to the fields of lighting and display technologies, and in particular, to a light-emitting device, a light-emitting substrate and a light-emitting apparatus.

### BACKGROUND

Organic light-emitting diodes (OLEDs) have characteristics of self-luminescence, wide viewing angle, quick response, high luminous efficiency, low operating voltage, small substrate thickness, being capable of being used for manufacturing a large-sized and bendable substrate, simple manufacturing process and the like, and is known as a next-generation “star” display technology.

### SUMMARY

In an aspect, a light-emitting device is provided. The light-emitting device includes a first electrode and a second electrode that are arranged sequentially, and a light-emitting layer disposed between the first electrode and the second electrode. A material of the light-emitting layer includes a host material and a guest material. The host material includes a p-type material and an n-type material, the p-type material and the n-type material form an exciplex, and the p-type material and the n-type material satisfy a following condition:

|HOMO_{p-type}−HOMO_{n-type}|≤0.2eV;

where HOMO_{p-type} represents a highest occupied molecular orbital (HOMO) energy level of the p-type material, and HOMO_{n-type} represents a HOMO energy level of the n-type material.

In some embodiments, the HOMO energy level of the n-type material is lower than the HOMO energy level of the p-type material.

In some embodiments, the p-type material and the n-type material further satisfy a following condition:

|LUMO_{n-type}|−|LUMO_{p-type}|≥0.2eV;

where LUMO_{p-type} represents a lowest unoccupied molecular orbital (LUMO) energy level of the p-type material, and LUMO_{n-type} represents a LUMO energy level of the n-type material.

In some embodiments, a ratio of a mass of the p-type material to a mass of the n-type material is greater than or equal to 2:8, and less than or equal to 8:2.

In some embodiments, the HOMO energy level of the p-type material is greater than or equal to −5.8 eV, and less than or equal to −5.3 eV; the HOMO energy level of the n-type material is greater than or equal to −6.0 eV, and less than or equal to −5.5 eV.

In some embodiments, a LUMO energy level of the p-type material is greater than or equal to −2.5 eV, and less than or equal to −2.0 eV; a LUMO energy level of the n-type material is greater than or equal to −2.8 eV, and less than or equal to −2.3 eV.

In some embodiments, a normalized fluorescence emission spectrum of the exciplex and a normalized fluorescence emission spectrum of the n-type material have an overlapping region therebetween, and an integral area of the overlapping region is greater than or equal to 90% of an integral area of the normalized fluorescence emission spectrum of the n-type material.

In some embodiments, an absolute value of a difference between a wavelength corresponding to a peak of a normalized fluorescence emission spectrum of the exciplex and a wavelength corresponding to a peak of a normalized fluorescence emission spectrum of the n-type material is less than or equal to 5 nm.

In some embodiments, a wavelength corresponding to a normalized fluorescence emission spectrum of the n-type material is in a range from 480 nm to 520 nm.

In some embodiments, a wavelength corresponding to a normalized fluorescence emission spectrum of the exciplex is in a range from 480 nm to 520 nm.

In some embodiments, a wavelength corresponding to a normalized fluorescence emission spectrum of the p-type material is in a range from 400 nm to 460 nm.

In some embodiments, a ratio of a hole mobility of the p-type material to an electron mobility of the n-type material is greater than or equal to 1:100, and less than or equal to 100:1.

In some embodiments, the hole mobility of the p-type material is greater than or equal to 1×10⁻⁸ cm²/v·s, and less than or equal to 1×10⁻⁴ cm²/v·s; the electron mobility of the n-type material is greater than or equal to 1×10⁻⁸ cm²/v·s, and less than or equal to 1×10⁻⁴ cm²/v·s.

In some embodiments, the p-type material is selected from any one of compounds represented by following general formula (a) and general formula (b):

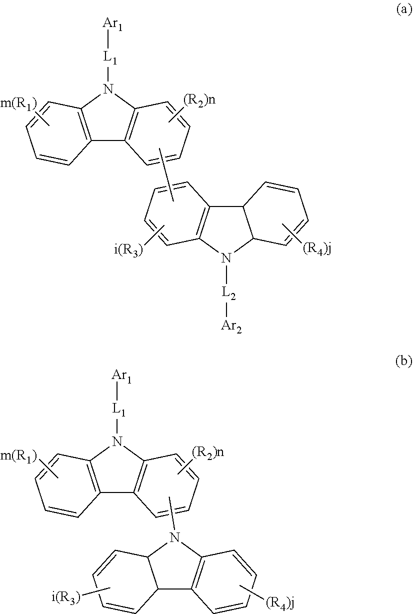

where R₁, R₂, R₃ and R₄ are the same or different, and are each independently selected from any one of deuterium, substituted or unsubstituted C₁ to C₁₀ alkyl, substituted or unsubstituted C₆ to C₃₀ aryl, and substituted or unsubstituted C₂ to C₃₀ heteroaryl; L₁ is selected from any one of a single bond, substituted or unsubstituted C₆ to C₃₀ arylene, and substituted or unsubstituted C₂ to C₃₀ heteroarylene; Ar₁ and Ar₂ are each independently selected from any one of substituted or unsubstituted C₆ to C₃₀ aryl, and substituted or unsubstituted C₂ to C₃₀ heteroaryl; m, n, i, j are each independently 0, 1 or 2.

In some embodiments, the n-type material is selected from any one of compounds represented by following general formula (i), general formula (ii) and general formula (iii):

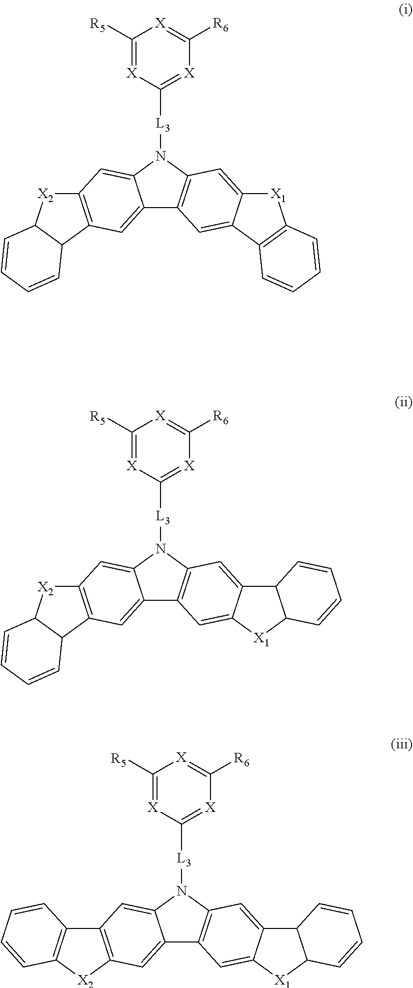

where X is selected from C(R) or N; X₁ and X₂ are the same or different, and are each independently selected from any one of N(R), O, S and Se; R₅, R₆ and R are the same or different, and are each independently selected from any one of hydrogen, deuterium, substituted or unsubstituted C₁ to C₁₀ alkyl, substituted or unsubstituted C₆ to C₃₀ aryl, and substituted or unsubstituted C₂ to C₃₀ heteroaryl; L₃ is selected from any one of a single bond, substituted or unsubstituted C₆ to C₃₀ arylene, and substituted or unsubstituted C₂ to C₃₀ heteroarylene.

In some embodiments, the light-emitting device further includes an electron blocking layer disposed between the first electrode and the light-emitting layer; the p-type material and a material of the electron blocking layer satisfy a following condition:

|HOMO_{p-type}|−|HOMO_{G′}|≤0.3eV;

where HOMO_{G′} represents a HOMO energy level of the material of the electron blocking layer.

In some embodiments, the light-emitting device further includes a hole blocking layer disposed between the second electrode and the light-emitting layer; the n-type material and a material of the hole blocking layer satisfy a following condition:

|LUMO_{HB}|−|LUMO_{n-type}|≤0.3eV;

where LUMO_{HB} represents a LUMO energy level of the material of the hole blocking layer, and LUMO_{n-type} represents a LUMO energy level of the n-type material.

In another aspect, a light-emitting substrate is provided. The light-emitting substrate includes a substrate, and a plurality of light-emitting devices disposed on the substrate. At least one light-emitting device of the plurality of light-emitting devices is the light-emitting device as described above.

In some embodiments, the HOMO energy level of the n-type material is lower than the HOMO energy level of the p-type material.

In yet another aspect, a light-emitting apparatus is provided. The light-emitting apparatus includes the light-emitting substrate as described above.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art can obtain other drawings according to these drawings. In addition, the accompanying drawings in the following description may be regarded as schematic diagrams, and are not limitations on actual sizes of products, actual processes of methods and actual timings of signals involved in the embodiments of the present disclosure.

FIG. 1 is a sectional view of a light-emitting substrate, in accordance with some embodiments;

FIG. 2 is a top view of a light-emitting substrate, in accordance with some embodiments;

FIG. 3 is a diagram showing an energy level relationship among a p-type material, an n-type material, a material of an electron blocking layer and a material of a hole blocking layer, in accordance with some embodiments;

FIG. 4 is a diagram showing normalized curves of an emission spectrum of a p-type material, an emission spectrum of an n-type material and an emission spectrum of an exciplex formed by the p-type material and the n-type material, in accordance with some embodiments; and

FIG. 5 is a diagram showing normalized curves of an emission spectrum of a p-type material, an emission spectrum of an n-type material and an emission spectrum of an exciplex formed by the p-type material and the n-type material, in accordance with the related art.

### DETAILED DESCRIPTION

Technical solutions in some embodiments of the present disclosure will be described clearly and completely below with reference to the accompanying drawings. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials or characteristics may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a plurality of” or “the plurality of” means two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” as used herein indicates an open and inclusive expression, which does not exclude devices that are applicable to or configured to perform additional tasks or steps.

Additionally, the phase “based on” as used herein is meant to be open and inclusive, since a process, a step, a calculation or other action that is “based on” one or more of the stated conditions or values may, in practice, be based on additional conditions or values beyond those stated.

As used herein, the term such as “about” or “approximately” includes a stated value and an average value within an acceptable range of deviation of a particular value. The acceptable range of deviation is determined by a person of ordinary skill in the art in view of measurement in question and errors associated with measurement of a particular quantity (i.e., limitations of a measurement system).

Exemplary embodiments are described herein with reference to sectional views and/or plan views as idealized exemplary drawings. In the accompanying drawings, thicknesses of layers and sizes of regions are enlarged for clarity. Thus, variations in shape relative to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of regions in a device, and are not intended to limit the scope of the exemplary embodiments.

Some embodiments of the present disclosure provide a light-emitting apparatus. The light-emitting apparatus includes a light-emitting substrate, and may, of course, further include other components such as a circuit used for providing an electrical signal for the light-emitting substrate to drive the light-emitting substrate to emit light. The circuit may be referred to as a control circuit, and may include a circuit board and/or an integrated circuit (IC) that each electrically connected to the light-emitting substrate.

In some embodiments, the light-emitting apparatus may be a lighting apparatus; in this case, the light-emitting apparatus serves as a light source for realizing a lighting function. For example, the light-emitting apparatus may be a backlight module in a liquid crystal display apparatus, a lamp used for internal or external lighting, a signal lamp, etc.

In some other embodiments, the light-emitting apparatus may be a display apparatus; in this case, the light-emitting substrate is a display substrate for realizing a function of displaying images (i.e., pictures). The light-emitting apparatus may include a display or a product including the display. The display may be a flat panel display (FPD), a micro display, etc. The display may be classified as a transparent display or a non-transparent display according to whether a user can see a scene behind the display. The display may be classified as a flexible display or a normal display (which may be referred to as a rigid display) according to whether the display can be bent or rolled. For example, the product including the display may include a computer display, a television, a billboard, a laser printer having a display function, a telephone, a mobile phone, a personal digital assistant (PDA), a laptop computer, a digital camera, a portable camcorder, a viewfinder, a vehicle, a large-area wall, a screen of a theater or a sign of a stadium.

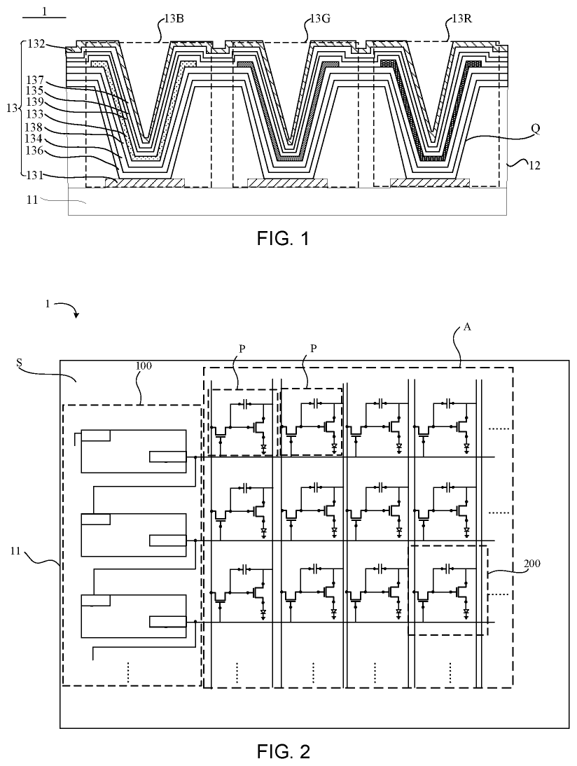

Some embodiments of the present disclosure provide a light-emitting substrate 1, as shown in FIG. 1, the light-emitting substrate 1 includes a substrate 11, and a pixel definition layer 12 and a plurality of light-emitting devices 13 that are disposed on the substrate 11. The pixel definition layer 12 has a plurality of openings Q, and the plurality of light-emitting devices 13 may be arranged in a one-to-one correspondence with the plurality of openings Q. Here, the plurality of light-emitting devices 13 may be all or part of light-emitting devices 13 included in the light-emitting substrate 1; the plurality of openings Q may be all or part of openings in the pixel definition layer 12.

In the plurality of light-emitting devices 13, at least one light-emitting device 13 may include a first electrode 131 and a second electrode 132 that are arranged sequentially, and a light-emitting layer 133 disposed between the first electrode 131 and the second electrode 132.

In some embodiments, as shown in FIG. 1, the first electrode 131 may be an anode; in this case, the second electrode 132 is a cathode. In some other embodiments, the first electrode 131 may be a cathode; in this case, the second electrode 132 is an anode.

In some embodiments, a material of the anode may be selected from high work function materials such as indium tin oxide (ITO), indium zinc oxide (IZO) or composite materials (e.g., silver (Ag)/ITO, aluminum (AI)/ITO, Ag/IZO or Al/IZO). “Ag/ITO” refers to a stacked structure stacked by a silver electrode and an ITO electrode. A material of the cathode may be selected from low work function materials such as Al, Ag, magnesium (Mg) or low work function metal alloy materials (e.g., Mg—Al alloy or Mg—Ag alloy).

For a light-emitting device of an organic light-emitting diode (OLED), a light-emitting principle of the light-emitting device 13 is that, through a circuit connected between the anode and the cathode, the anode injects holes into the light-emitting layer 133, the cathode injects electrons into the light-emitting layer 133, the electrons and the holes that are injected form excitons in the light-emitting layer 133, and the excitons are each back to a ground state through a manner of radiative transition, so as to emit photons.

As shown in FIG. 1, in order to improve an efficiency of injecting the electrons and the holes into the light-emitting layer 133, the light-emitting device 13 may further include at least one of a hole transporting layer (HTL) 134, an electron transporting layer (ETL) 135, a hole injection layer (HIL) 136 and an electron injection layer (EIL) 137. For example, the light-emitting device 13 may further include the hole transporting layer (HTL) 134 disposed between the anode and the light-emitting layer 133, and the electron transporting layer (ETL) 135 disposed between the cathode and the light-emitting layer.

In order to further improve the efficiency of injecting the electrons and the holes into the light-emitting layer 133, the light-emitting device 13 may further include the hole injection layer (HIL) 136 disposed between the anode and the hole transporting layer 134, and the electron injection layer (EIL) 137 disposed between the cathode and the electron transporting layer 135.

In some embodiments, a material of the electron transporting layer 135 may be selected from organic materials having good electron transmission properties; alternatively, the material of the electron transporting layer 135 may be selected from the organic materials doped with LiQ₃, lithium (Li), calcium (Ca) or the like. A thickness of the electron transporting layer 135 may be in a range from 10 nm to 70 nm. A material of the hole transporting layer 134 may be selected from any one of N,N′-Bis-(1-naphthalenyl)-N,N′-bis-phenyl-(1,1′-biphenyl)-4,4′-diamine and 4,4′-cyclohexylidenebis[N,N-bis(p-tolyl)aniline].

In some other embodiments, a material of the electron injection layer 137 may be selected from low work function metals such as Li, Ca and ytterbium (Yb); alternatively, the material of the electron injection layer 137 may be selected from metal salts such as lithium fluoride (LiF) and LiQ₃. A thickness of the electron injection layer 137 may be in a range from 0.5 nm to 2 nm. A material of the hole injection layer 136 may be selected from copper(II) phthalocyanine (CuPc), hexaazatriphenylenehexacabonitrile (HATCN) or manganese trioxide (MnO₃); alternatively, the material of the hole injection layer 136 may be selected from materials obtained by performing P-type doping on these materials. A thickness of the hole injection layer 136 may be in a range from 5 nm to 30 nm.

The light-emitting substrate 1 may be further provided with driving circuits connected to respective light-emitting devices 13 therein, and the driving circuits may be connected to the control circuit to drive the respective light-emitting devices 13 to emit light according to the electrical signal input by the control circuit. The driving circuits may be each an active driving circuit or a passive driving circuit.

The light-emitting substrate 1 may emit white light, monochromatic light (i.e., single-color light) or color-tunable light.

In a first example, the light-emitting substrate 1 may emit the white light. In this case, as shown in FIG. 1, the plurality of light-emitting devices 13 may include a light-emitting device 13R that emits red light, a light-emitting device 13G that emits green light and a light-emitting device 13B that emits blue light. The light-emitting device 13B that emits the blue light, the light-emitting device 13R that emits the red light and the light-emitting device 13G that emits the green light are controlled to emit light simultaneously, which may achieve light mixing of the light-emitting device 13B that emits the blue light, the light-emitting device 13R that emits the red light and the light-emitting device 13G that emits the green light, thereby enabling the light-emitting substrate 1 to emit the white light.

In this example, the light-emitting substrate 1 may be used for lighting. That is, the light-emitting substrate 1 may be applied to a lighting apparatus.

In a second example, the light-emitting substrate 1 may emit the monochromatic light. In this case, there are two possible situations. In a first situation, the plurality of light-emitting devices include light-emitting devices 13R that emit red light, light-emitting devices 13G that emit green light and light-emitting devices 13B that emit blue light, and the light-emitting substrate 1 may emit monochromatic light by controlling the light-emitting devices that emit the same monochromatic light to emit light. In a second situation, the plurality of light-emitting devices include only light-emitting devices that emit a same monochromatic light, such as the light-emitting devices 13G that emit green light, and the light-emitting substrate 1 may emit the monochromatic light by controlling the plurality of light-emitting devices to emit light. In this example, the light-emitting substrate 1 may be used for lighting. That is, the light-emitting substrate 1 may be applied to a lighting apparatus. Alternatively, the light-emitting substrate 1 may be used for displaying images or pictures of a single color. That is, the light-emitting substrate 1 may be applied to a display apparatus.

In a third example, the light-emitting substrate 1 may emit the color-tunable light (i.e., colored light). The plurality of light-emitting devices 13 included in the light-emitting substrate 1 are similar to the plurality of light-emitting devices 13 as described in the first example in structure. A color and luminance of mixed light emitted by the light-emitting substrate 1 may be controlled by controlling luminance of each light-emitting device 13, thereby achieving emitting the colored light.

In this example, the light-emitting substrate 1 may be used for displaying images or pictures. That is, the light-emitting substrate 1 may be applied to a display apparatus. Of course, the light-emitting substrate 1 may be applied to a lighting apparatus.

In the third example, in an example where the light-emitting substrate 1 is a display substrate such as a full color display panel, as shown in FIG. 2, the light-emitting substrate 1 includes a display area A and a peripheral area S disposed around the display area A. The display area A includes a plurality of sub-pixel regions P. Each sub-pixel region P corresponds to an opening, and an opening corresponds to a light-emitting device. Each sub-pixel region P is provided with a pixel driving circuit 200 used for driving a respective light-emitting device to emit light therein. The peripheral region S is used for wiring. For example, the peripheral region S is used for arranging a gate driving circuit 100 connected to the pixel driving circuits 200.

In some embodiments, a material of a light-emitting layer of at least one light-emitting device 13 may include a host material and a guest material, the host material is a material having characteristics of a capability to transfer energy with the guest material, a reversible electrochemical redox reaction, a good and matched capability to transport holes and electrons, a good thermal stability and a good film-forming property, and the host material has a relatively large proportion in the light-emitting layer 133. The guest material may be, for example, a phosphor luminescent material, and the guest material has a relatively small proportion in the light-emitting layer 133.

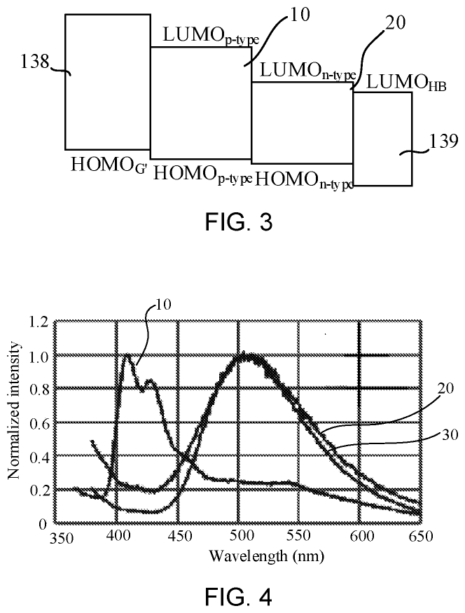

In some embodiments, as shown in FIG. 3, the host material may include a p-type material 10 and an n-type material 20, and the p-type material 10 and the n-type material 20 form an exciplex. That is, the host material is a dual-host material.

The exciplex refers to an aggregation of two different molecules or atoms. In an excited state, the two different molecules or atoms have a relatively strong interaction and generate a new energy level, an emission spectrum of the aggregation is different from that of a single material, and the aggregation has no fine structure.

In these embodiments, the p-type material 10 may be regarded as an electron donor material, the n-type material 20 may be regarded as an electron acceptor material, and the exciplex is formed, under a condition of photo-excitation or electro-excitation, in a film formed by the p-type material 10 and the n-type material 20. In this case, the electron acceptor material in an excited state and of the electron donor material in a ground state interact to form the exciplex in a charge-transfer state to emit light, and the exciplex has a new spectrum that is distinct from an emission spectrum of the p-type material 10 and an emission spectrum of the n-type material 20.

In some embodiments, the p-type material 10 and the n-type material 20 satisfy a following condition:

|HOMO_{p-type}−HOMO_{n-type}|≤0.2eV.

HOMO_{p-type} represents a highest occupied molecular orbital (HOMO) energy level of the p-type material 10, and HOMO_{n-type} represents a HOMO energy level of the n-type material 20.

In these embodiments, compared with a conventional exciplex in which a difference between a HOMO energy level of a p-type material and a HOMO energy level of an n-type material is relatively large in the related art, the HOMO energy level of the p-type material 10 and the HOMO energy level of the n-type material 20 are relatively close to each other, an overlapping degree of the HOMO energy levels is large, which may improve an exciton utilization ratio of the host material, and enable the host material to have a high fluorescence quantum efficiency. As a result, energy may be enabled to be transferred from the host material to the guest material more efficiently, so as to improve a luminous efficiency. In addition, it can be found through experiments that, compared with the conventional exciplex, of which an emission spectrum exhibits a significant red shift relative to an emission spectrum of the n-type material, in the related art, an emission spectrum of the host material including the p-type material 10 and the n-type material 20 and the emission spectrum of the n-type material 20 have a relatively large overlap therebetween, which may reduce a red shift. As a result, the energy may be further enabled to be transferred from the host material to the guest material more efficiently, so as to improve the luminous efficiency.

In some embodiments, as shown in FIG. 3, the HOMO energy level HOMO_{n-type} of the n-type material 20 is lower than the HOMO energy level HOMO_{p-type} of the p-type material 10. That is, the HOMO energy level of the n-type material 20 is deeper than the HOMO energy level of the p-type material 10.

In some embodiments, the HOMO energy level of the p-type material 10 is greater than or equal to −5.8 eV, and less than or equal to −5.3 eV; the HOMO energy level of the n-type material 20 is greater than or equal to −6.0 eV, and less than or equal to −5.5 eV.

In this case, in a case where the HOMO energy level of the n-type material 20 is lower than the HOMO energy level of the p-type material 10, if the HOMO energy level of the p-type material 10 is −5.8 eV, the HOMO energy level of the n-type material 20 may be −5.9 eV or −6.0 eV; if the HOMO energy level of the p-type material 10 is −5.3 eV, the HOMO energy level of the n-type material 20 may be −5.4 eV or −5.5 eV; if the HOMO energy level of the p-type material 10 is −5.5 eV, the HOMO energy level of the n-type material 20 may be −5.6 eV or −5.7 eV.

In some embodiments, the p-type material 10 and the n-type material 20 further satisfy a following condition:

|LUMO_{n-type}|−|LUMO_{p-type}|≥0.2eV;

LUMO_{p-type} represents a lowest unoccupied molecular orbital (LUMO) energy level of the p-type material 10, and LUMO_{n-type} represents a LUMO energy level of the n-type material 20.

That is, the LUMO energy level of the n-type material 20 is deeper than the LUMO energy level of the p-type material 10, and a difference between the LUMO energy level of the n-type material 20 and the LUMO energy level of the p-type material 10 is relatively large, which is conducive to forming the exciplex between the p-type material 10 and the n-type material 20.

In some embodiments, the LUMO energy level of the p-type material 10 is greater than or equal to −2.5 eV, and less than or equal to −2.0 eV; the LUMO energy level of the n-type material 20 is greater than or equal to −2.8 eV, and less than or equal to −2.3 eV.

In this case, in a case where the LUMO energy level of the n-type material 20 is lower than the LUMO energy level of the p-type material 10, if the LUMO energy level of the p-type material 10 is −2.5 eV, the LUMO energy level of the n-type material 20 may be −2.8 eV or −2.7 eV; if the LUMO energy level of the p-type material 10 is −2.0 eV, the LUMO energy level of the n-type material 20 may be −2.2 eV, −2.3 eV, −2.4 eV, −2.5 eV, −2.8 eV or the like; if the LUMO energy level of the p-type material 10 is −2.3 eV, the LUMO energy level of the n-type material 20 may be −2.5 eV, −2.6 eV, −2.7 eV, −2.8 eV or the like.

A mass ratio of the p-type material 10 to the n-type material 20 to be mixed is not specifically limited as long as the exciplex can be formed after the p-type material 10 and the n-type material 20 are mixed. According to a fact that the exciplex may be formed between two interfaces or formed in a same film layer, it can be seen that a mass of the p-type material 10 may be equivalent to a mass of the n-type material 20, or the mass of one of the p-type material 10 and the n-type material 20 may be much greater than the mass of the other thereof.

In some embodiments, a ratio of the mass of the p-type material 10 to the mass of the n-type material 20 is greater than or equal to 2:8, and less than or equal to 8:2.

In some embodiments, as shown in FIG. 4, a normalized fluorescence emission spectrum of the exciplex 30 and a normalized fluorescence emission spectrum of the n-type material 20 have an overlapping region therebetween, and an integral area of the overlapping region is greater than or equal to 90% of an integral area of the normalized fluorescence emission spectrum of the n-type material 20.

In these embodiments, it can be found through experiments that, in a case where the ratio of the mass of the p-type material 10 to the mass of the n-type material 20 varies from small to large, the integral area of the overlapping region between the normalized fluorescence emission spectrum of the exciplex 30 and the normalized fluorescence emission spectrum of the n-type material 20 is always greater than or equal to 90% of the integral area of the normalized fluorescence emission spectrum of the n-type material 20. In application, in a case where the p-type material 10 and the n-type material 20 exist in a form of the exciplex, the energy may be enabled to be transferred from the host material to the guest material more efficiently, so as to improve the luminous efficiency.

In some embodiments, as shown in FIG. 4, an absolute value of a difference between a wavelength corresponding to a peak of the normalized fluorescence emission spectrum of the exciplex 30 and a wavelength corresponding to a peak of the normalized fluorescence emission spectrum of the n-type material 20 is less than or equal to 5 nm. It can be found through experiments that, in the case where the ratio of the mass of the p-type material 10 to the mass of the n-type material 20 varies from small to large, the absolute value of the difference between the wavelength corresponding to the peak of the normalized fluorescence emission spectrum of the exciplex 30 and the wavelength corresponding to the peak of the normalized fluorescence emission spectrum of the n-type material 20 is always less than or equal to 5 nm. In application, similarly, the energy may be enabled to be transferred from the host material to the guest material more efficiently, so as to improve the luminous efficiency.

In some embodiments, as shown in FIG. 4, a wavelength corresponding to the normalized fluorescence emission spectrum of the n-type material 20 is in a range from 480 nm to 520 nm. The n-type material 20 may be a material for emitting the green light. That is, the light-emitting device may be the light-emitting device that emits the green light.

In some embodiments, a wavelength corresponding to the normalized fluorescence emission spectrum of the exciplex 30 is in a range from 480 nm to 520 nm. It can be seen from above that the host material is a material for emitting the green light. According to a fact that the wavelength corresponding to the normalized fluorescence emission spectrum of the n-type material 20 is also in a range from 480 nm to 520 nm, it can be seen that the emission spectrum of the host material almost completely overlaps with the emission spectrum of the n-type material 20, so that the red shift is relatively small.

In some embodiments, a wavelength corresponding to a normalized fluorescence emission spectrum of the p-type material 10 is in a range from 400 nm to 460 nm. The p-type material 10 may be a material for emitting blue light, which facilitates energy transfer.

In some embodiments, a ratio of a hole mobility of the p-type material 10 to an electron mobility of the n-type material 20 is greater than or equal to 1:100, and less than or equal to 100:1. According to a fact that the p-type material 10 is a hole injection material, and the n-type material 20 is an electron injection material, it can be seen that the host material may achieve a double injection of the holes and the electrons to promote a balance of a carrier transport, and it is possible to meet usage requirements by limiting the ratio of the hole mobility of the p-type material 10 to the electron mobility of the n-type material 20 within the above range.

In some embodiments, the hole mobility of the p-type material 10 is greater than or equal to 1×10⁻⁸ cm²/v·s, and less than or equal to 1×10⁻⁴ cm²/v·s; the electron mobility of the n-type material 20 is greater than or equal to 1×10⁻⁸ cm²/v·s, and less than or equal to 1×10⁻⁴ cm²/v·s.

In some embodiments, the p-type material 10 may be selected from any one of compounds represented by following general formula (a) and general formula (b):

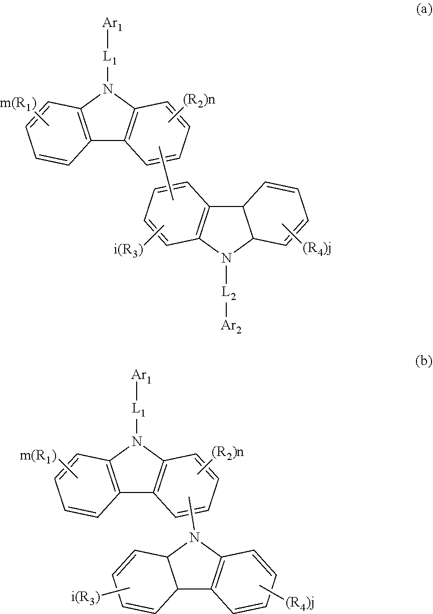

R₁, R₂, R₃ and R₄ are the same or different, and are each independently selected from any one of deuterium, substituted or unsubstituted C₁ to C₁₀ alkyl, substituted or unsubstituted C₆ to C₃₀ aryl, and substituted or unsubstituted C₂ to C₃₀ heteroaryl; L₁ is selected from any one of a single bond, substituted or unsubstituted C₆ to C₃₀ arylene, and substituted or unsubstituted C₂ to C₃₀ heteroarylene; Ar₁ is selected from any one of substituted or unsubstituted C₆ to C₃₀ aryl, and substituted or unsubstituted C₂ to C₃₀ heteroaryl; m, n, i, j are each independently 0, 1 or 2.

In a case where m, n, i, and j are each 0, the general formula (a) may be as shown in a following formula (a_1), and the general formula (b) may be as shown in a following formula (b_1):

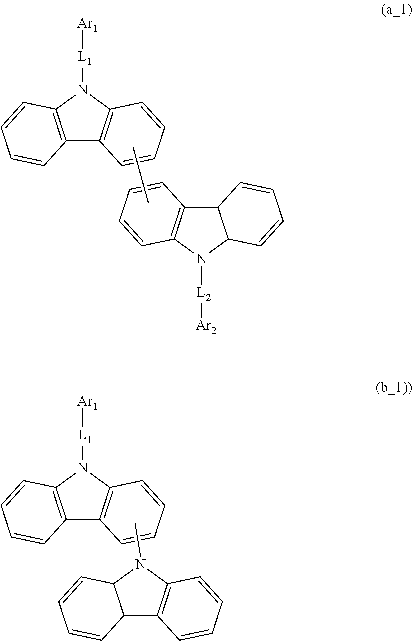

In this case, a connection between two carbazoles in the general formula (a) may be as shown in any one of following formulas (a_11), (a_12), (a_13) or (a_14). A connection between two carbazoles in the general formula (b) may be as shown in any one of following formulas (b_1), (b_12), (b_13) or (b_14).

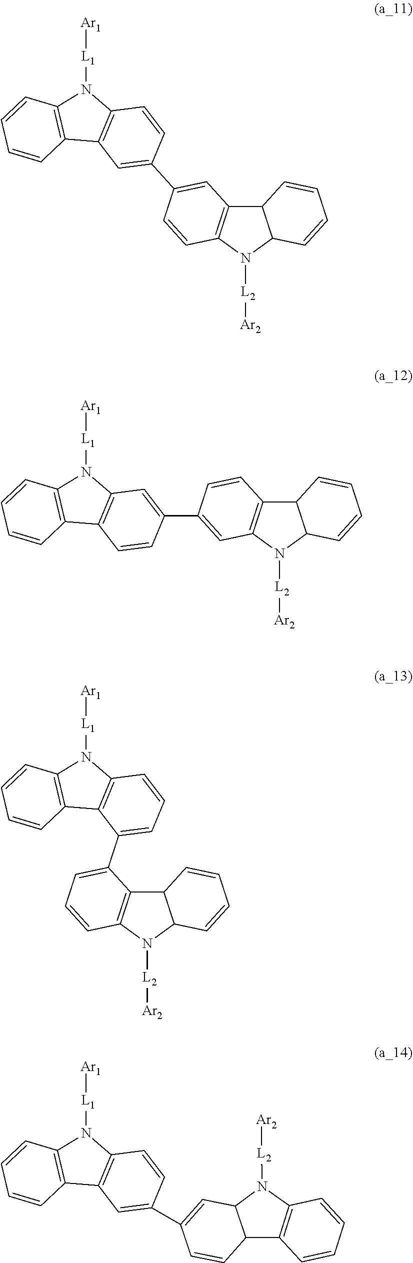

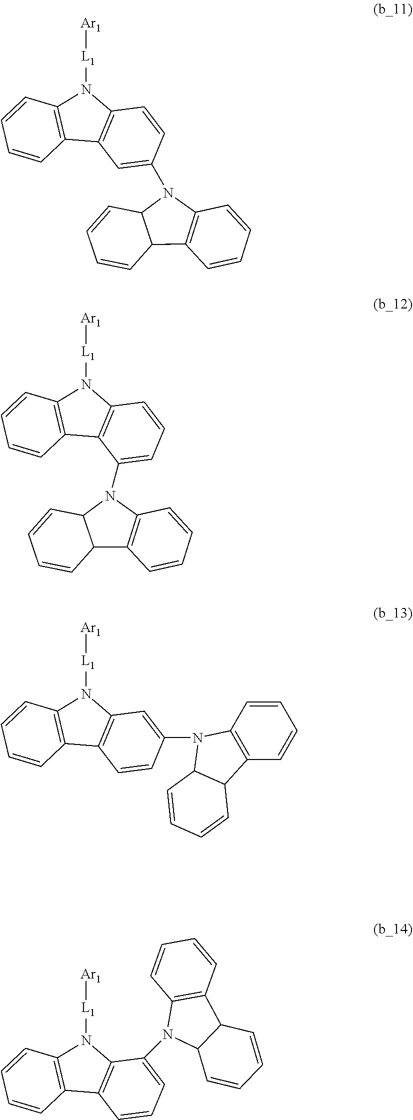

In a case where L₁ and L₂ are each a single bond, the general formula (a) may be as shown in a following formula (a_2); in a case where L₁ is a single bond, the general formula (b) may be as shown in a following formula (b_2)

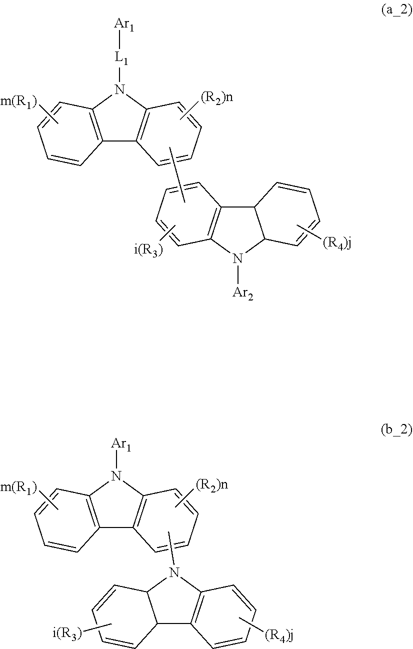

In some embodiments, the p-type material is selected from any one of compounds having following structural formulas:

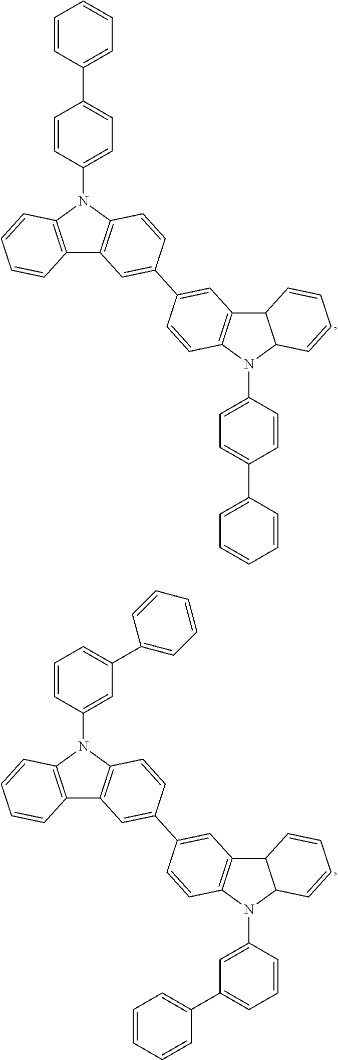 [SMILES: C1=CC2c3cc(-c4ccc5c(c4)c4ccccc4n5-c4ccc(-c5ccccc5)cc4)ccc3N(c3ccc(-c4ccccc4)cc3)C2C=C1 ; C1=CC2c3cc(-c4ccc5c(c4)c4ccccc4n5-c4cccc(-c5ccccc5)c4)ccc3N(c3cccc(-c4ccccc4)c3)C2C=C1]

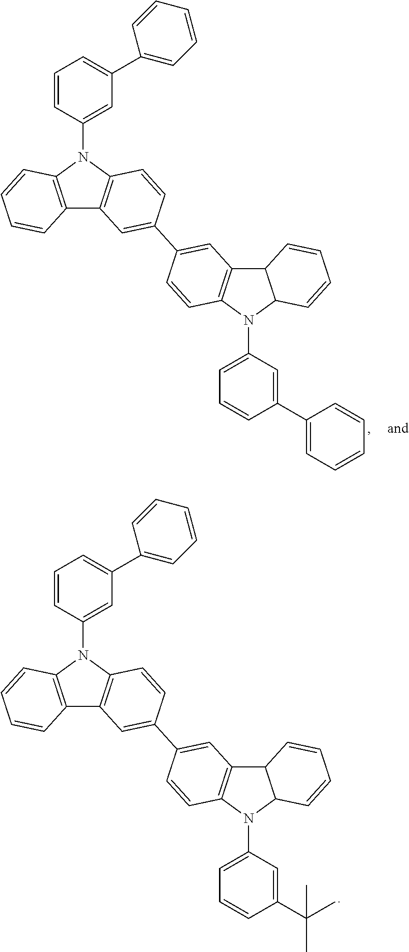 [SMILES: C1=CC2c3cc(-c4ccc5c(c4)c4ccccc4n5-c4cccc(-c5ccccc5)c4)ccc3N(c3cccc(-c4ccccc4)c3)C2C=C1 ; CC(C)(C)c1cccc(N2c3ccc(-c4ccc5c(c4)c4ccccc4n5-c4cccc(-c5ccccc5)c4)cc3C3C=CC=CC32)c1]

In some embodiments, the n-type material is selected from any one of compounds represented by following general formula (i) general formula (ii) and general formula (iii):

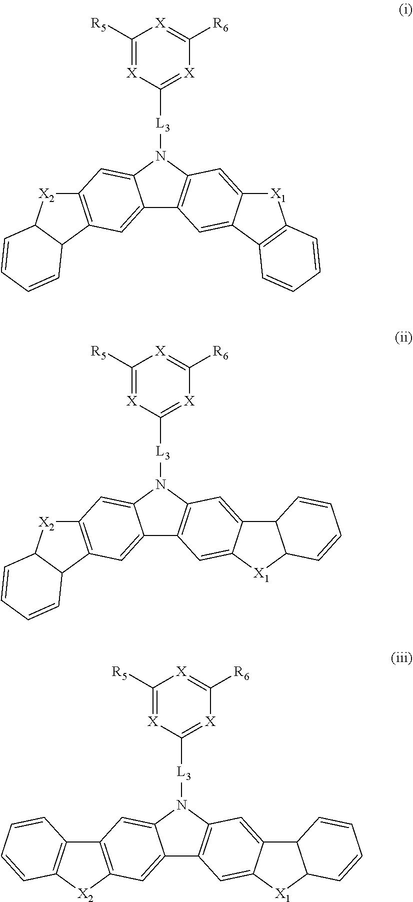

X is selected from C(R) or N; X₁ and X₂ are the same or different, and are each independently selected from any one of N(R), oxygen (O), sulfur (S) and selenium (Se); R₅, R₆ and R are the same or different, and are each independently selected from any one of hydrogen, deuterium, substituted or unsubstituted C₁ to C₁₀ alkyl, substituted or unsubstituted C₆ to C₃₀ aryl, and substituted or unsubstituted C₂ to C₃₀ heteroaryl; L₃ is selected from any one of a single bond, substituted or unsubstituted C₆ to C₃₀ arylene, and substituted or unsubstituted C₂ to C₃₀ heteroarylene.

In a case where X is N, and X₁ and X₂ are each O, the general formula (i) may be as shown in a following formula (i_1), the general formula (ii) may be as shown in a following formula (ii_1), and the general formula (iii) may be as shown in a following formula (iii_1):

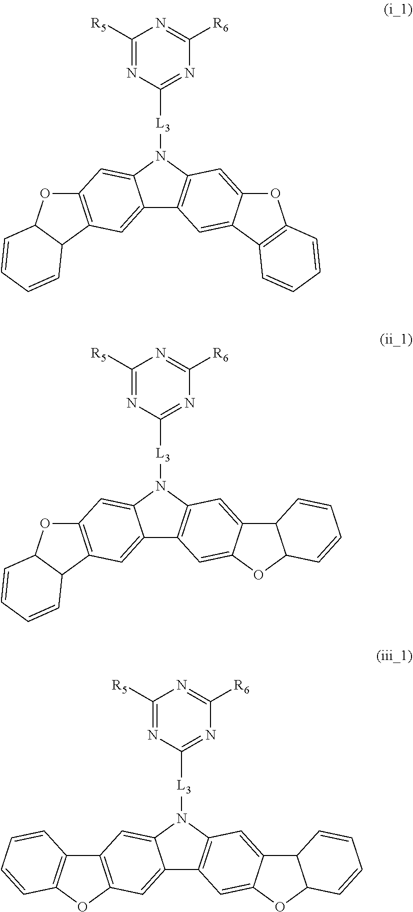

In a case where R₅ and R₆ are each hydrogen, the general formula (i) may be as shown in a following formula (i_2), the general formula (ii) may be as shown in a following formula (ii_2), and the genera formula (iii) may be as shown in a following formula (iii_2):

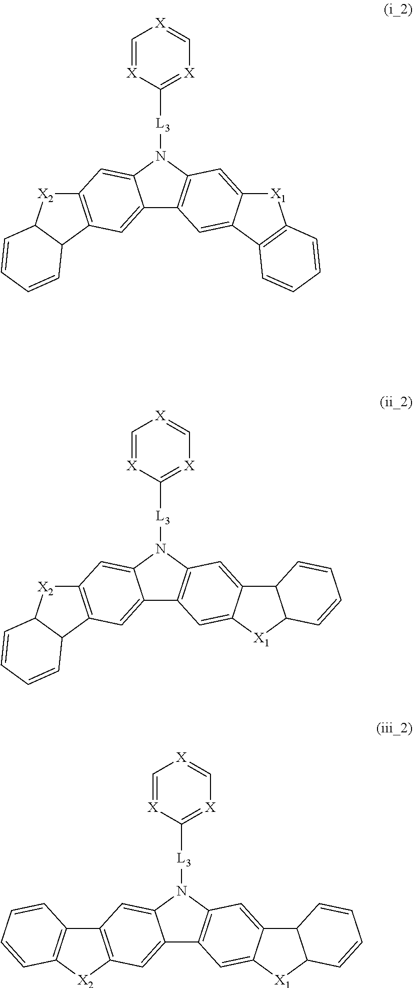

In a case where L₃ is a single bond, the general formula (i) may be as shown in a following formula (i_3), the general formula (ii) may be as shown in a following formula (ii_3), and the general formula (iii) may be as shown in a following formula (iii_3):

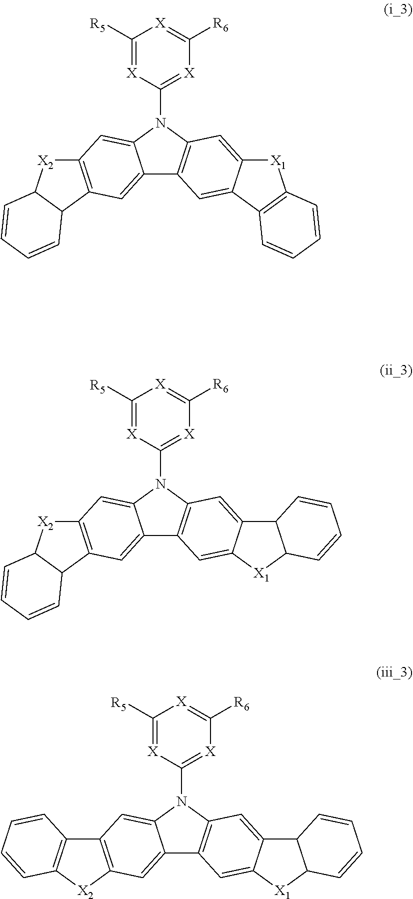

In these embodiments, compared with the n-type material 20′ in the related art, a large conjugated electron donating group is introduced in the n-type material 20, so that the HOMO energy level of the n-type material 20 may be made shallow. As a result, the HOMO energy level of the p-type material 10 and the HOMO energy level of the n-type material 20 are enabled to be close to each other, the overlapping degree of the HOMO energy levels is relatively large, and the host material has a high fluorescence quantum efficiency, thereby enabling the energy to be transferred from the host material to the guest material more efficiently to improve the luminous efficiency.

In some embodiments, the n-type material is selected from any one of compounds having following structural formulas:

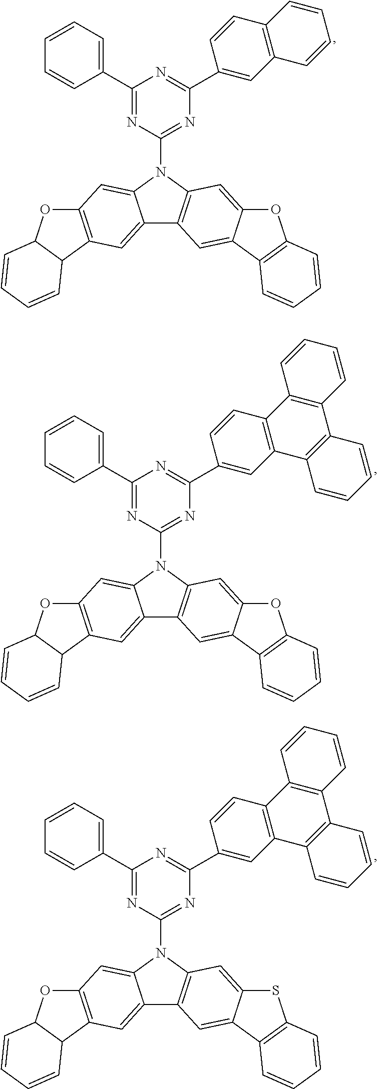

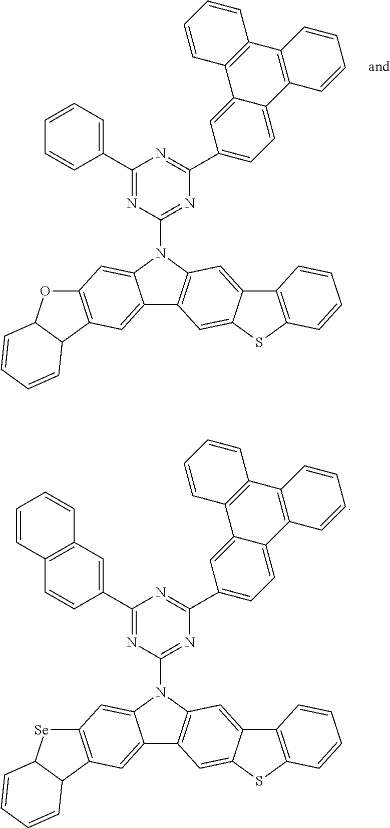 [SMILES: C1=CC2Oc3cc4c(cc3C2C=C1)c1cc2sc3ccccc3c2cc1n4-c1nc(-c2ccccc2)nc(-c2ccc3c4ccccc4c4ccccc4c3c2)n1 ; C1=CC2[Se]c3cc4c(cc3C2C=C1)c1cc2sc3ccccc3c2cc1n4-c1nc(-c2ccc3ccccc3c2)nc(-c2ccc3c4ccccc4c4ccccc4c3c2)n1]

In some embodiments, as shown in FIG. 1, the light-emitting device 13 further includes an electron blocking layer (EBL) 138 disposed between the first electrode 131 and the light-emitting layer 133, and the electron blocking layer 138 may be located between the hole transporting layer 134 and the light-emitting layer 133. As shown in FIG. 3, the p-type material 10 and a material of the electron blocking layer 138 satisfy a following condition:

|HOMO_{p-type}|−|HOMO_{G′}|≤0.3eV.

The HOMO_{G′} represents a HOMO energy level of the material of the electron blocking layer 138.

In these embodiments, the electron blocking layer 138 is provided, which may have an effect of blocking the electrons transported by the light-emitting layer 133 from diffusing, so as to confine the electrons in a light-emitting region. In addition, a difference between the HOMO energy level of the p-type material and the HOMO energy level of the material of the electron blocking layer 138 is limited within the above range, so that a material of the electron blocking layer 138 and the p-type material 10 have a relatively small difference in the HOMO energy level. As a result, an injection barrier of holes between the electron blocking layer 138 and the light-emitting layer 133 may be reduced, thereby reducing an operating voltage. Moreover, a relatively low injection barrier may reduce a charge accumulation at an interface to delay an interface degradation, thereby prolonging a lifetime of the device.

In some embodiments, N-(9,9′-spirobi[fluoren]-2-yl)-N(9,9-diphenyl-9H-fluoren-3-yl)dibenzo[b,d]furan-3-amine may be selected as the material of the electron blocking layer 138.

In some embodiments, as shown in FIG. 1, the light-emitting device 13 further includes a hole blocking layer (HBL) 139 disposed between the second electrode 132 and the light-emitting layer 133. The hole blocking layer 139 may be located between the electron transporting layer 135 and the light-emitting layer 133. As shown in FIG. 3, the n-type material 20 and a material of the hole blocking layer 139 satisfy a following condition:

|LUMO_{HB}|−|LUMO_{n-type}|≤0.3eV;

The LUMO_{HB} represents a LUMO energy level of the material of the hole blocking layer 139, and the LUMO_{n-type} represents the LUMO energy level of the n-type material 20.

In these embodiments, the hole blocking layer 139 is provided, which may have an effect of blocking the holes transported by the light-emitting layer 133 from diffusing, so as to confine the holes in the light-emitting region. In addition, a difference between the LUMO energy level of the n-type material 20 and the LUMO energy level of the material of the hole blocking layer 139 is limited within the above range, so that a material of the hole blocking layer 139 and the n-type material 20 have a relatively small difference in the LUMO energy level. As a result, an injection barrier of electrons between the hole blocking layer 139 and the light-emitting layer 133 may be reduced, thereby reducing the operating voltage. Moreover, a relatively low injection barrier may reduce a charge accumulation at an interface to delay an interface degradation, thereby prolonging the lifetime of the device.

In some embodiments, 2,9-dimethyl-4,7-diphenyl-1,10-Phenanthroline may be selected as the material of the hole blocking layer (HBL) 139.

In order to objectively describe technical effects of the embodiments provided in the present disclosure, the embodiments of the present disclosure will be exemplarily described in detail though a comparative example and an experimental example as follows.

It will be noted that in the comparative example and the experimental example as follows, the light-emitting devices 13 have a same structure including the anode, the hole injection layer (HIL) 136, the hole transporting layer (HTL) 134, the electron blocking layer (EBL) 138, the light-emitting layer 133, the hole blocking layer (HBL) 139, the electron transporting layer (ETL) 135, the electron injection layer (EIL) 137 and the cathode. Moreover, except the light-emitting layer 133, the same functional layer in different light-emitting devices is made of a same material. Here, ITO is selected as the material of the anode; CuPc is selected as the material of the hole injection layer 136; N,N′-Bis-(1-naphthalenyl)-N,N′-bis-phenyl-(1,1′-biphenyl)-4,4′-diamine is selected as the material of the hole transporting layer 134; N-(9,9′-spirobi[fluoren]-2-yl)-N(9,9-diphenyl-9H-fluoren-3-yl)dibenzo[b,d]furan-3-amine is selected as the material of the electron blocking layer 138; 2,9-dimethyl-4,7-diphenyl-1,10-Phenanthroline is selected as the material of the hole blocking layer 139; LiQ₃ is selected as the material of the electron transporting layer 135; LiF is selected as the material of the electron injection layer 137; Mg—Ag alloy is selected as the material of the cathode. In addition, in any one of the comparative example and the experimental example as follows, the mass ratio of the p-type material to the n-type material in the host material GH of the light-emitting layer 133 is 5:5, and the exciplex is formed; the mass proportion of the guest material GD in the light-emitting layer 133 is 10%; a thickness of the light-emitting layer 133 is 35 nm.

### Comparative Example

In the comparative example, in the host material GH in the light-emitting layer 133, a structure represented by p_1 as follows is selected as the p-type material 10′, and a structure represented by n_1 as follows is selected as the n-type material 20′. A structure represented by m_1 as follows is selected as the guest material GD.

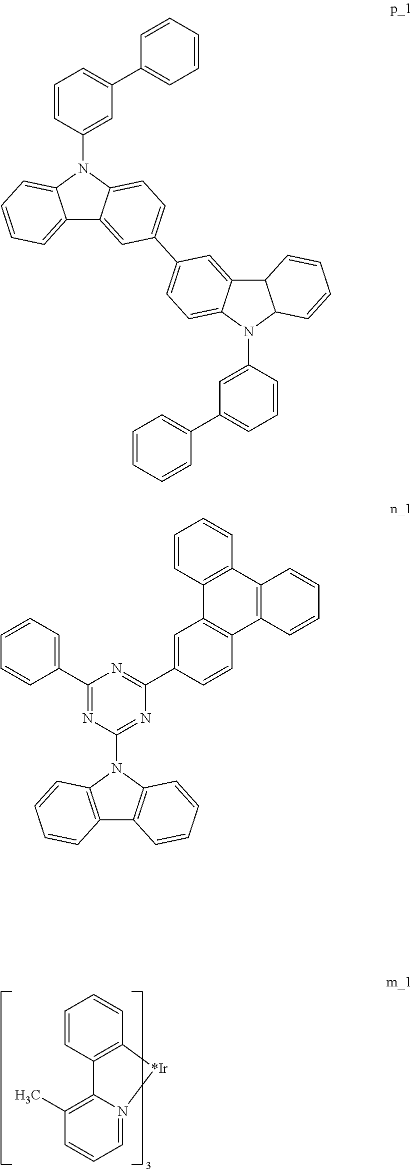

### Experimental Example

In the experimental example, in the host material GH in the light-emitting layer 133, a structure represented by p_2 as follows is selected as the p-type material 10, and a structure represented by n_2 as follows is selected as the n-type material 20. The guest material GD is the same as the guest material GD in the comparative example.

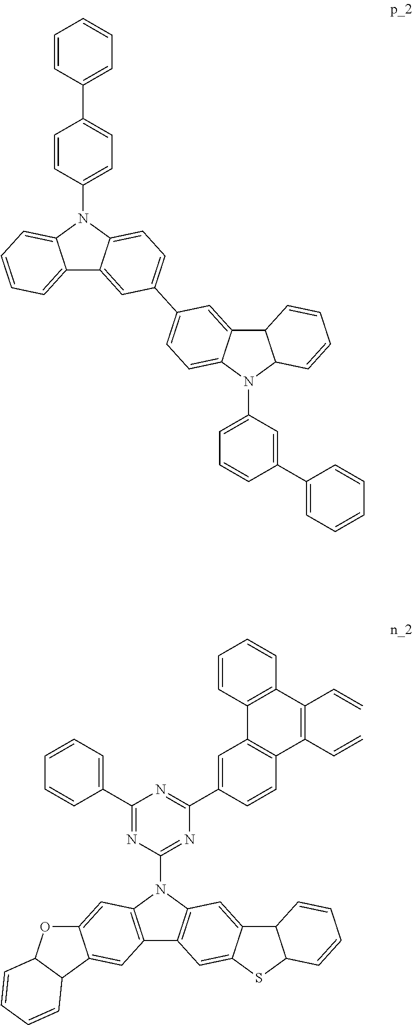 [SMILES: C1=CC2c3cc(-c4ccc5c(c4)c4ccccc4n5-c4ccc(-c5ccccc5)cc4)ccc3N(c3cccc(-c4ccccc4)c3)C2C=C1 ; C=Cc1c(C=C)c2ccc(-c3nc(-c4ccccc4)nc(-n4c5cc6c(cc5c5cc7c(cc54)C4C=CC=CC4S7)C4C=CC=CC4O6)n3)cc2c2ccccc12]

Data of the energy levels and the mobility of the p-type materials and the n-type materials respectively in the comparative example and the experimental example are as shown in Table 1 below.

TABLE 1

| Name | HOMO | LUMO | S1 | T1 | Mobility |
|---|---|---|---|---|---|
| p_1 | −5.41 | −2.14 | 3.06 | 2.92 | Hole mobility |
| | | | | | μₕ = 5.4 × 10⁻⁶ |
| n_1 | −5.86 | −2.52 | 2.82 | 2.68 | Electron mobility |
| | | | | | μₑ = 7.5 × 10⁻⁷ |
| p_2 | −5.39 | −2.08 | 3.02 | 2.89 | Hole mobility |
| | | | | | μₕ = 6.4 × 10⁻⁶ |
| n_2 | −5.50 | −2.48 | 2.43 | 2.28 | Electron mobility |
| | | | | | μₑ = 5.8 × 10⁻⁷ |

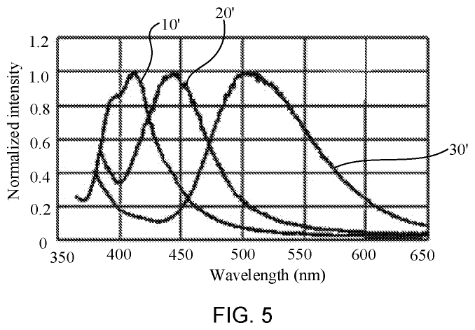

A diagram showing normalized curves of emission spectra of the p-type material 10′, the n-type material 20′ and the exciplex 30′ formed by the p-type material 10′ and the n-type material 20′ in the comparative example is as shown in FIG. 5. A diagram showing normalized curves of emission spectra of the p-type material 10, the n-type material 20 and the exciplex 30 formed by the p-type material 10 and the n-type material 20 in the experimental example is as shown in FIG. 4.

With reference to Table 1 and FIGS. 4 and 5, it can be seen that the HOMO energy level of the n-type material 20 may be made shallow by introducing the large conjugated electron donating group into the n-type material 20, so that the overlapping degree of HOMO orbitals of the p-type material 10 and the n-type material 20 may be improved.

Compared with the exciplex 30′, of which the emission spectrum exhibits a relatively large red shift, in the related art, the emission spectrum of the exciplex 30 in the embodiments of the present disclosure almost completely overlaps with the emission spectrum of the n-type material 20, so that the exciplex 30 has luminous characteristics different from the conventional exciplex 30′, in the related art, of which the emission spectrum exhibits the significant red shift relative to the emission spectrum of the n-type material 20′.

The driving voltage, the current efficiency, the chromaticity coordinates and the lifetime of the light-emitting devices 13 respectively obtained in the comparative example and the experimental example are tested, and obtained results are as shown in Table 2 below.

TABLE 2

| | Driving | | | | |
|---|---|---|---|---|---|
| Name | voltage/V | Cd/A | CIEx | CIEy | LT95(h) |
| Comparative | 112% | 86% | 0.25 | 0.72 | 82% |
| example | | | | | |
| Experimental | 100% | 100% | 0.25 | 0.72 | 100% |
| example | | | | | |

In Table 2, the driving voltages are measured by providing a same current density. Cd represents the current efficiencies, in ampere A, which are also measured by providing a same current density. CIE is a chromaticity diagram, CIEx represents the X value of the chromaticity coordinates in the chromaticity diagram, and CIEy represents the Y value of the chromaticity coordinates in the chromaticity diagram. LT95(h) represents the lifetime of the devices that referring to a duration for luminance to decay to 95% of initial luminance under a same current density.

With reference to Table 1 and Table 2, it can be seen that the HOMO energy level of the n-type material 20 may be made shallow by introducing the large conjugated electron donating group into the n-type material 20, which may improve the overlapping degree of the HOMO orbitals of the p-type material 10 and the n-type material 20 and enable the host material GH to have the relatively high fluorescence quantum efficiency. As a result, the energy may be enabled to be transferred from the host material GH to the guest material GD more efficiently, thereby reducing the driving voltage, improving the luminous efficiency and prolonging the lifetime. In addition, through a comparison of the chromaticity coordinates, it can be found that, in the embodiments of the present disclosure, a color purity of the guest material GD during light emission is not affected.

In conclusion, by introducing the large conjugated electron donating group into the n-type material 20, the HOMO energy level of the n-type material 20 may be made shallow, and the overlapping degree of the HOMO orbitals of the p-type material 10 and the n-type material 20 is improved, which is different from a case where the difference between the HOMO energy levels of the p-type material 10′ and the n-type material 20′, that for forming the exciplex 30′ in the related art, is relatively large. As a result, the exciton utilization ratio of the host material GH may be improved, the host material GH may be enabled to have the relatively high fluorescence quantum efficiency, and the luminous efficiency may be greatly improved when the host material GH is applied to the light-emitting device, thereby having unexpected technical effects.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A light-emitting device, comprising:
a first electrode and a second electrode that are arranged sequentially; and
a light-emitting layer disposed between the first electrode and the second electrode; wherein
a material of the light-emitting layer includes a host material and a guest material; and
the host material includes a p-type material and an n-type material, the p-type material and the n-type material form an exciplex, and the p-type material and the n-type material satisfy a following condition:

|HOMO_{p-type}−HOMO_{n-type}|≤0.2eV;
HOMO_{p-type} represents a highest occupied molecular orbital (HOMO) energy level of the p-type material, and HOMO_{n-type} represents a HOMO energy level of the n-type material.

2. The light-emitting device according to claim 1, wherein
the HOMO energy level of the n-type material is lower than the HOMO energy level of the p-type material.

3. The light-emitting device according to claim 1, wherein the p-type material and the n-type material further satisfy a following condition:

|LUMO_{n-type}|−|LUMO_{p-type}|≥0.2eV;
wherein LUMO_{p-type} represents a lowest unoccupied molecular orbital (LUMO) energy level of the p-type material, and LUMO_{n-type} represents a LUMO energy level of the n-type material.

4. The light-emitting device according to claim 1, wherein
a ratio of a mass of the p-type material to a mass of the n-type material is greater than or equal to 2:8, and less than or equal to 8:2.

5. The light-emitting device according to claim 1, wherein
the HOMO energy level of the p-type material is greater than or equal to −5.8 eV, and less than or equal to −5.3 eV; and
the HOMO energy level of the n-type material is greater than or equal to −6.0 eV, and less than or equal to −5.5 eV.

6. The light-emitting device according to claim 1, wherein
a LUMO energy level of the p-type material is greater than or equal to −2.5 eV, and less than or equal to −2.0 eV; and
a LUMO energy level of the n-type material is greater than or equal to −2.8 eV, and less than or equal to −2.3 eV.

7. The light-emitting device according to claim 1, wherein
a normalized fluorescence emission spectrum of the exciplex and a normalized fluorescence emission spectrum of the n-type material have an overlapping region therebetween, and an integral area of the overlapping region is greater than or equal to 90% of an integral area of the normalized fluorescence emission spectrum of the n-type material.

8. The light-emitting device according to claim 1, wherein
an absolute value of a difference between a wavelength corresponding to a peak of a normalized fluorescence emission spectrum of the exciplex and a wavelength corresponding to a peak of a normalized fluorescence emission spectrum of the n-type material is less than or equal to 5 nm.

9. The light-emitting device according to claim 1, wherein
a wavelength corresponding to a normalized fluorescence emission spectrum of the n-type material is in a range from 480 nm to 520 nm.

10. The light-emitting device according to claim 1, wherein
a wavelength corresponding to a normalized fluorescence emission spectrum of the exciplex is in a range from 480 nm to 520 nm.

11. The light-emitting device according to claim 1, wherein
a wavelength corresponding to a normalized fluorescence emission spectrum of the p-type material is in a range from 400 nm to 460 nm.

12. The light-emitting device according to claim 1, wherein
a ratio of a hole mobility of the p-type material to an electron mobility of the n-type material is greater than or equal to 1:100, and less than or equal to 100:1.

13. The light-emitting device according to claim 12, wherein
the hole mobility of the p-type material is greater than or equal to 1×10⁻⁸ cm²/v·s, and less than or equal to 1×10⁻⁴ cm²/v·s; and
the electron mobility of the n-type material is greater than or equal to 1×10⁻⁸ cm²/v·s, and less than or equal to 1×10⁻⁴ cm²/v·s.

14. The light-emitting device according to claim 1, wherein
the p-type material is selected from any one of compounds represented by following general formula (a) and general formula (b): 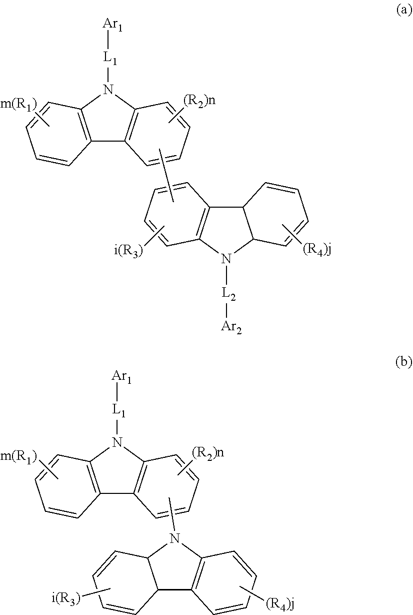
wherein R₁, R₂, R₃ and R₄ are the same or different, and are each independently selected from any one of deuterium, substituted or unsubstituted C₁ to C₁₀ alkyl, substituted or unsubstituted C₆ to C₃₀ aryl, and substituted or unsubstituted C₂ to C₃₀ heteroaryl;
L₁ is selected from any one of a single bond, substituted or unsubstituted C₆ to C₃₀ arylene, and substituted or unsubstituted C₂ to C₃₀ heteroarylene;
Ar₁ and Ar₂ are each independently selected from any one of substituted or unsubstituted C₆ to C₃₀ aryl, and substituted or unsubstituted C₂ to C₃₀ heteroaryl; and
m, n, i, j are each independently 0, 1 or 2.

15. The light-emitting device according to claim 1, wherein
the n-type material is selected from any one of compounds represented by following general formula (i), general formula (ii) and general formula (iii): 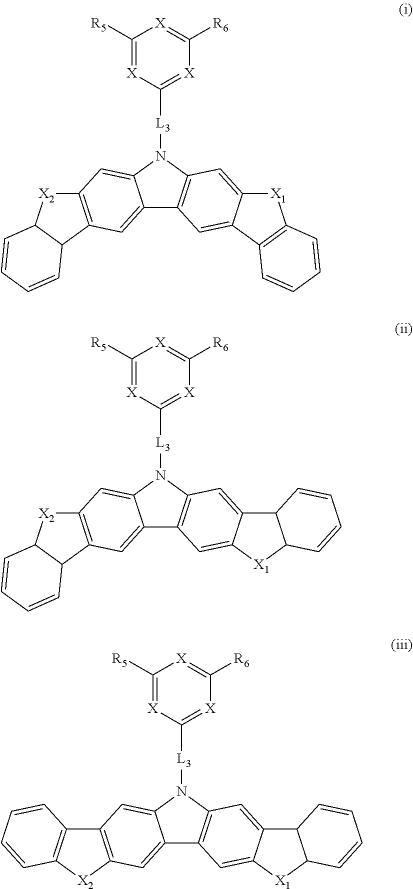
wherein X is selected from C(R) or N; X₁ and X₂ are the same or different, and are each independently selected from any one of N(R), O, S and Se;
R₅, R₆ and R are the same or different, and are each independently selected from any one of hydrogen, deuterium, substituted or unsubstituted C₁ to C₁₀ alkyl, substituted or unsubstituted C₆ to C₃₀ aryl, and substituted or unsubstituted C₂ to C₃₀ heteroaryl; and
L₃ is selected from any one of a single bond, substituted or unsubstituted C₆ to C₃₀ arylene, and substituted or unsubstituted C₂ to C₃₀ heteroarylene.

16. The light-emitting device according to claim 1, further comprising an electron blocking layer disposed between the first electrode and the light-emitting layer; wherein
the p-type material and a material of the electron blocking layer satisfy a following condition:

|HOMO_{p-type}|−|HOMO_{G′}|≤0.3eV;
wherein HOMO_{G′} represents a HOMO energy level of the material of the electron blocking layer.

17. The light-emitting device according to claim 1, further comprises a hole blocking layer disposed between the second electrode and the light-emitting layer;
the n-type material and a material of the hole blocking layer satisfy a following condition:

|LUMO_{HB}|−|LUMO_{n-type}|≤0.3eV;
wherein LUMO_{HB} represents a LUMO energy level of the material of the hole blocking layer, and LUMO_{n-type} represents a LUMO energy level of the n-type material.

18. A light-emitting substrate, comprising:
a substrate; and
a plurality of light-emitting devices disposed on the substrate;
wherein at least one light-emitting device of the plurality of light-emitting devices is the light-emitting device according to claim 1.

19. A light-emitting apparatus, comprising the light-emitting substrate according to claim 18.

20. The light-emitting substrate according to claim 18, wherein
the HOMO energy level of the n-type material is lower than the HOMO energy level of the p-type material.
